(19) United States
(12) Patent Application Publication
(10) Pub. No.: US 2008/0237184 A1
(43) Pub. Date: Oct. 2, 2008

(54) METHOD AND APPARATUS FOR PLASMA PROCESSING

(76) Inventors: MAMORU YAKUSHIJI, Shunan (JP); Yutaka Ohmoto, Hikari (JP); Yutaka Kouzuma, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/846,899

(22) Filed: Aug. 29, 2007

(30) Foreign Application Priority Data
Mar. 30, 2007 (JP) 2007-090407

(51) Int. Cl. H01L 21/306

(52) U.S. Cl. 216/67; 156/345.1

(57) ABSTRACT

A plasma processing apparatus comprising a vacuum vessel; a process chamber housed in the vacuum vessel; and a sample stage located in the process chamber, for supporting on its upper surface a disk-like sample to be processed; wherein plural disk-like samples are continuously processed with plasma generated in the process chamber and wherein during the idling time between the successive processes the temperature of the sample stage is adjusted to a predetermined value higher than the temperature at which the samples are processed.

### BACKGROUND OF THE INVENTION

This invention relates to an apparatus and a method for plasma processing wherein a disk-like sample such as a semiconductor wafer is placed in the process chamber housed in a vacuum vessel and the sample is processed with plasma generated in the process chamber, and more particularly to an apparatus and a method for plasma processing wherein the sample is placed on the temperature-controllable sample stage located in the process chamber and the sample is processed while the temperature of the sample stage is being kept at values suitable for the process of the sample.

In the case where a disk-like sample such as a semiconductor wafer is processed with such a plasma processing apparatus as mentioned above, it is customary to keep the wafer at the optimal temperature while it is being processed so as to improve the working precision in wafer surface treatment. There are known a technique wherein the temperature of the sample is controlled by controlling the temperature of the coolant circulated in the sample stage on which the sample is placed, and a technique wherein the temperatures of the sample stage and the sample itself are controlled with a heater disposed in the sample stage.

Japanese patent documents, JP-A-2006-286733 and JP-A-2006-351887, disclose such conventional techniques as described just above. According to JP-A-2006-286733, the cooling medium to be fed into the coolant duct in the sample stage is heated by a heater provided in the coolant line leading to the coolant duct so that the cooling medium can be fed into the coolant duct after its temperature has been adjusted to a desired value.

According to JP-A-2006-351887, on the other hand, the temperature of the sample stage is adjusted to a desired value by controlling the temperature of the cooling medium passed through the sample stage on which the sample is placed. Namely, before processing the sample, the temperature of the sample stage is raised to temperatures to be reached in processing, then the temperature of the sample stage is adjusted to a desired value by lowering the temperature of the cooling medium, and finally the high frequency power starts being supplied to the electrode disposed within the sample stage.

### SUMMARY OF THE INVENTION

As the number of processed samples increases, byproducts produced as a result of having processed samples with plasma adhere to and accumulate on, the inner surface of the wall of the process chamber housed in the vacuum vessel. As the accumulation of such byproducts proceeds, fragments may come off the accumulation, some fragments may be transferred within the process chamber by being carried on some vehicle, and they may finally adhere onto the sample surface. Thus, they will become foreign materials which contaminate the processed samples and therefore reduce the yield in the process.

Also, such byproducts may adhere to the upper surface of the sample stage from which the sample is dismounted during the time between the end of processing one sample and the start of processing the next sample. Accordingly, when the next sample is placed on the sample stage in the next process, the byproducts may contaminate the lower surface of the sample. It is therefore necessary to prevent such byproducts from adhering to the sample stage to avoid the adverse influence due to the contamination with such byproducts. Those prior art techniques have not taken this point into consideration.

Namely, the conventional techniques have not taken into consideration the problem that byproducts produced in the etching process adhere to the upper surface of the sample stage (hereafter referred to also as “sample resting electrode”) to adversely affect the working precision in the following processes. Even in the cleaning of the internal of the process chamber without any wafer therein, such byproducts may adhere to the upper surface of the sample resting electrode. Conventionally, in order to suppress this adverse effect, it is customary that either the temperature of the coolant circulated in the sample resting electrode must be controlled when processing is interrupted, i.e. during the idling time, or the plasma cleaning must be performed before the idling time.

However, the change in the temperature of the coolant takes a relatively long time since the coolant has a large heat capacity, and this reduces the efficiency of process. Likewise, if plasma cleaning is performed during the idling time or before processing, it must be performed several times to render the upper surface of the sample stage free of contamination with byproducts, resulting in poor process efficiency. That is, the throughput has been very low with the conventional techniques wherein the removal of byproducts from the upper surface of the sample stage is attempted while the sample is not being processed.

The object of this invention is to provide a plasma processing apparatus or a plasma processing method wherein the process efficiency can be improved by suppressing the contamination of samples with byproducts.

The object of this invention can be achieved by a plasma processing apparatus comprising a vacuum vessel; a process chamber housed in the vacuum vessel; and a sample stage located in the process chamber, for supporting on its upper surface a disk-like sample to be processed; wherein plural disk-like samples are continuously processed with plasma generated in the process chamber and wherein during the idling time between the successive processes the temperature of the sample stage is adjusted to a predetermined one higher than the temperature at which the samples are processed.

Also, the object of this invention can be achieved by a plasma processing method wherein plural disk-like samples, each of which is placed on the upper surface of the sample stage located in the process chamber housed in the vacuum vessel, are continuously processed with plasma generated in the process chamber, and wherein during the idling time between the successive processes the temperature of the sample stage is adjusted to a predetermined value higher than the temperature at which the samples are processed.

Further, the object of this invention can be achieved by adjusting the temperature of the sample stage to the predetermined value by a heater provided in the sample stage. Still further, the object of this invention can be achieved by choosing the predetermined value independently of the processing conditions under which the plural samples are processed.

Yet further, the object of this invention can be achieved by a film-like heater embedded in the dielectric film which is disposed on the upper surface of the sample stage and on which the sample is placed.

A plasma processing method wherein plural disk-like samples, each of which is placed on the upper surface of the sample stage located in the process chamber housed in the vacuum vessel, are continuously processed with plasma generated in the process chamber, and wherein during the idling time between the successive processes the temperature of the sample stage is adjusted to a predetermined one higher than the temperature at which the samples are processed.

The recent increase in the scale of integration in semiconductor devices has accompanied the further miniaturization of the structure of each circuit element of an electronic device. Consequently, the circuit element which could be built in a single layer in the past, has come to be built in a layer structure consisting of plural layers stacked one upon another to meet a requirement of improving operational characteristics. In the field of printed circuit boards, for example, material for wiring conductor has been aluminum and the wiring conductor has been of single layer. However, the recent requirement for improving the operational reliability and the resolution in advanced photographic technique, has made it necessary to replace the conventional aluminum single layer by a composite layer, or laminated, structure consisting of an upper and a lower layers of titanium nitride with aluminum layer interposed between them. Further, the recent requirement for increasing the switching speeds of transistors and decreasing the consumption of power in transistors, has made it customary to build the gate electrode in a laminated structure.

In the case where such a laminated structure is worked with etching throughout, the temperature of the sample resting electrode, i.e. sample stage on which the sample is placed when it is processed, is controlled by circulating coolant through the coolant duct cut in the sample resting electrode. This temperature control is necessary since working precision can be improved by adjusting the temperature of wafer to the optimal value during etching operation. When the etching operation is completed, the wafer is dismounted from the sample resting electrode and transferred out of the process chamber. During the idling time (while etching operation is interrupted until the next etching operation is resumed), the temperature of the coolant circulating through the duct in the sample resting electrode is kept at the same temperature as that of the coolant maintained during etching operation. Now, if the temperature of the coolant through the sample resting electrode is lower than the temperature of the material of which the process chamber is made, then the byproducts produced during the etching operation adhere to the sample resting electrode. When a new wafer is mounted on the sample resting electrode for the next etching operation, the byproducts deposited on the sample resting electrode contaminates the new wafer so that etching characteristic may be adversely affected.

Conventionally, during the idling time, it is customary to suppress the adhesion of byproducts onto the sample resting electrode by adjusting the temperature of the coolant through the sample resting electrode to a relatively high value. However, it takes time to raise the coolant temperature high enough to suppress the adhesion of byproducts and it also takes time to adjust the coolant temperature to the optimal value for the following etching operation. Further, plasma cleaning is performed after each etching operation so as to suppress the adhesion of byproducts onto the sample resting electrode during the idling time. Thus, according to the conventional techniques, considerable time is needed to suppress the adhesion of byproducts onto the sample resting electrode during the idling time and therefore the throughput of the process is very poor. Therefore, there has been need for a procedure capable of suppressing the adhesion of byproducts onto the sample resting electrode without lowering the throughput of process.

This invention has been made to meet such industrial requirements and its constitution, usages and advantages will be explained in the following by way of embodiments.

Other objects, features and advantages of the invention will become apparent from the following description of the embodiments of the invention taken in conjunction with the accompanying drawings.

### BRIEF DESCRIPTION OF THE DRAWINGS

FIG. 1 schematically shows in vertical cross section the structure of a plasma processing apparatus as an embodiment of this invention;

FIG. 2 schematically shows in vertical cross section the structure of the sample resting electrode used in the plasma processing apparatus shown in FIG. 1;

FIG. 3 shows in block diagram the circuit of a temperature control system for the sample resting electrode shown in FIG. 2;

FIG. 4 is a table listing the conditions for the etching operation performed by the plasma processing apparatus shown in FIG. 1;

FIG. 5 shows the steps of a procedure carried out between two successive lots by the plasma processing apparatus shown in FIG. 1;

FIG. 6 graphically shows the change with time in the temperature of the sample resting electrode used in the plasma processing apparatus shown in FIG. 1;

FIG. 7 shows the steps of a procedure carried out for a lot by the plasma processing apparatus shown in FIG. 1;

FIG. 8 graphically shows the change with time in the temperature of the sample resting electrode used in the plasma processing apparatus shown in FIG. 1;

FIG. 9 graphically shows the change with time in the temperature of the sample resting electrode used in the plasma processing apparatus shown in FIG. 1;

FIG. 10 shows the steps of a procedure carried out for no-wafer cleaning by the plasma processing apparatus shown in FIG. 1;

FIG. 11 graphically shows the change with time in the temperature of the sample resting electrode used in the plasma processing apparatus shown in FIG. 1;

FIG. 12 graphically shows the change with time in the temperature of the sample resting electrode used in the plasma processing apparatus shown in FIG. 1; and

FIG. 13 graphically shows the change with time in the temperature of the sample resting electrode used in the plasma processing apparatus shown in FIG. 1.

### DESCRIPTION OF THE EMBODIMENTS

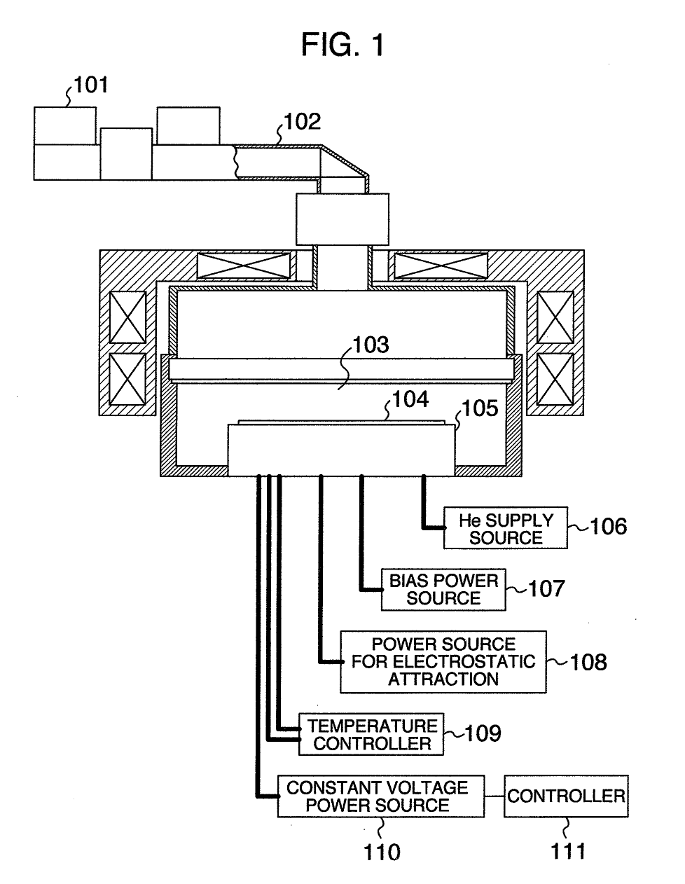

The embodiments of this invention will now be described below with reference to the attached drawings. FIG. 1 schematically shows in vertical cross section the structure of a plasma processing apparatus as an embodiment of this invention.

In the plasma processing apparatus shown as an embodiment of this invention in FIG. 1, microwaves generated by a microwave generating source 101 are propagated through a waveguide 102. A process chamber 103 is communicated with an evacuating system (not shown) and a gas feed system (not shown) so that the internal of the process chamber 103 can be depressurized to a pressure condition suitable for plasma processing. Gas fed into the process chamber 103 is turned into plasma by being excited by the microwaves guided into the process chamber 103. Accordingly, a disk-like sample 104 (hereafter referred to as wafer) to be processed can be subjected to a desired plasma processing. Alternatively, plasma may be generated by the inductive coupling procedure using high frequency electric power or the electrostatic coupling procedure using high frequency electric power, in place of the above mentioned procedure using microwaves.

The wafer 104 is mounted on a sample resting electrode 105 and a bias potential is applied to the sample resting electrode 105 from a bias power source 107 connected thereto. Accordingly, ions in the plasma bombard the surface of the wafer 104 to perform plasma processing. Further, the sample resting electrode 105 is coupled to a helium (He) supply source 106 for securing the heat transfer between the wafer 104 and the electrode 105, a DC power source 108 for electrostatic attraction, a constant voltage power source 110 for controlling the heater temperature and a temperature controller 109 for circulating temperature-controlled coolant through the sample resting electrode 105 to cool the body of the electrode 105. The constant voltage power source 110 is also connected with a controller 111 for determining the output voltage of the constant voltage power source 110.

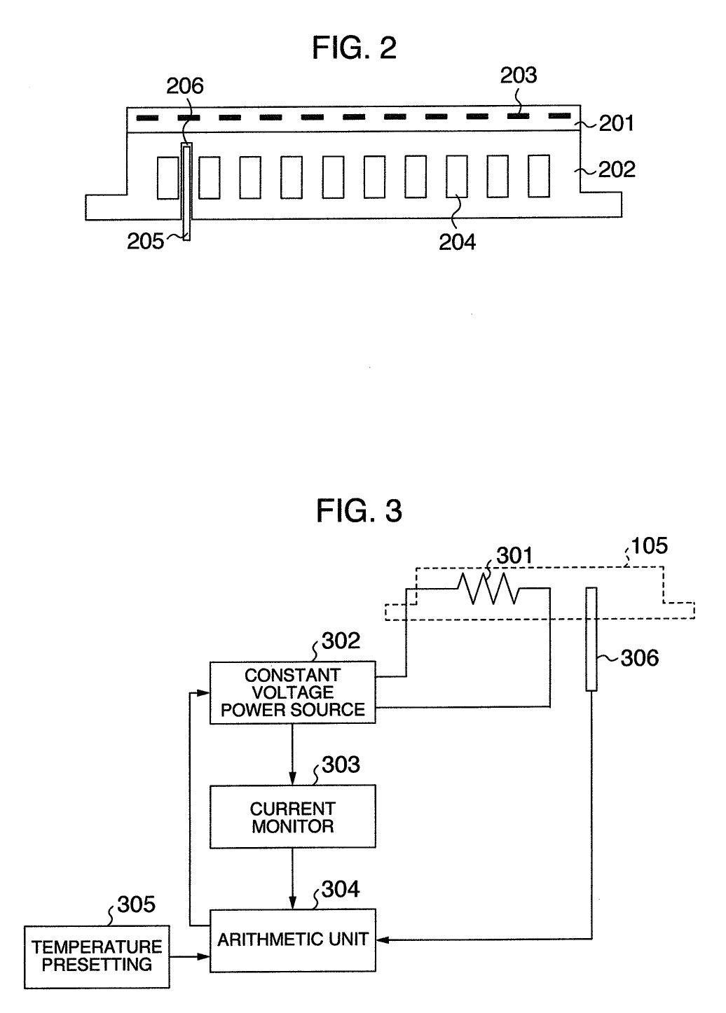

FIG. 2 schematically shows in vertical cross section the structure of the sample resting electrode 105 used in the plasma processing apparatus shown in FIG. 1. The sample resting electrode 105 consists mainly of a head plate 201 and a cooling plate 202. The head plate 201 is made of insulating material and has a heater 203 for heat generation embedded therein. The heater 203 is connected with the constant voltage power source 110 shown in FIG. 1. In the cooling plate 202 is cut a coolant passage 204 through which the coolant, whose temperature is controlled by the temperature controller 109 shown in FIG. 1, is passed. A small hole is bored in a lower peripheral portion of the cooling plate 202 and a temperature sensor 205 is inserted in the small hole.

FIG. 3 shows in block diagram the circuit of a temperature control system for controlling the power source for the heater 203. A heater resistor 301 is connected with a constant voltage power source 302 which controls the temperature of the sample resting electrode 105 by receiving the voltage command signal from an arithmetic unit 304 and applying an appropriate voltage to the heater resistor 301. The arithmetic unit 304 delivers the voltage command signal for keeping the sample resting electrode 105 at a preset temperature 305 depending on the output signals of a current monitor 303 and a temperature sensor 306. Accordingly, the wafer 104 or the sample resting electrode 105 is adjusted to a desired temperature. Thus, the temperature control system consists of a single signal loop.

Description will now be made of an embodiment of this invention which relates to a method wherein power is supplied to the heater disposed in the sample resting electrode 105 during the idling time, the temperature of the electrode 105 is elevated, and the adhesion of byproducts is suppressed. First, after the completion of etching process, the wafer 104 is dismounted from the sample resting electrode 105 and transferred out of the process chamber 103. During the idling time, that is, while there is no wafer on the electrode 105, a voltage is applied across the heater resistor 301. As shown in FIG. 3, since the voltage applied to the heater resistor 301 from the constant voltage power source 302 is controlled by the arithmetic unit 304 depending on the output signal of the temperature sensor 306, that is, since this control is performed by a signal loop consisting of the circuit elements 301, 302, 304 and 306, then the sample resting electrode 105 is heated up to a preset temperature 305 very quickly and kept stably at the preset temperature 305 thereafter. The preset temperature 305 is preferably a temperature high enough to suppress the adhesion of byproducts and the sample resting electrode 105 is always kept at the preset temperature all through the idling time. Immediately before the start of the next etching operation, the supply of power to the heater resistor 301 is stopped so that the temperature of the sample resting electrode may be adjusted to a value suitable for etching.

The operation of the heater 203 may be controlled in such a manner that the temperature at which the sample resting electrode 105 is maintained during the idling time is realized by obtaining through a communication means the value that is preset by a user depending on the sorts and structure of layers in the surface of the wafer 104 and that is stored in a memory device (not shown). Alternatively, a control device including the controller 111 of the plasma processing apparatus may control the heater 203 on the basis of the command data (recipe) for controlling the operations related to plural conditions for processing plural wafers 104, the command data (recipe) previously including the temperature at which the sample resting electrode 105 is maintained during the idling time.

According to this embodiment, the temperature of the sample resting electrode 105 or the temperature of its upper surface during the idling time can be set independent of the processing conditions including the temperatures of the wafers treated before and after the idling time and the status of the apparatus in operation. For example, the control device, which receives the signals transmitted from the sensors located at various points in the plasma processing apparatus, may calculate the value of temperature at which the sample resting electrode 105 is maintained on the basis of the system parameters derived from the received signals or the value of the temperature may be read out of a memory device. Therefore, the operating mode of the plasma processing apparatus during processing the wafer 104 and the operating mode of the plasma processing apparatus during the idling time between successive processes, are set independent of each other. In the embodiment described below, the temperature at which the sample resting electrode 105 is maintained during the idling time is set constant for plural wafers, independent of the temperatures at which the wafers are processed.

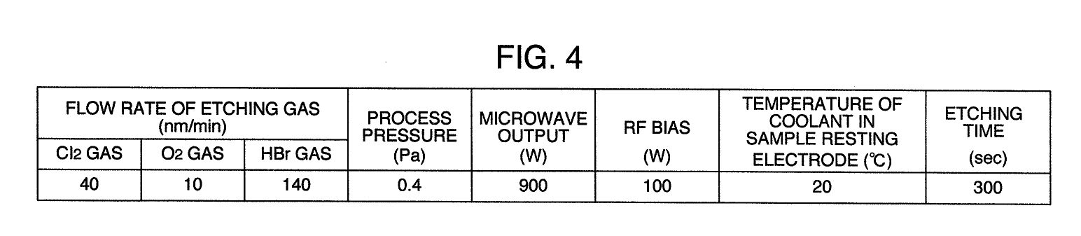

The effect of suppressing the adhesion of byproducts onto the surface of the sample resting electrode will now be recognized according to this embodiment. FIG. 4 is a table listing the conditions for the etching operation performed by the plasma processing apparatus shown in FIG. 1. Twenty-five bare wafers of silicon were processed successively under the etching conditions as shown in FIG. 4. Then, during the idling time thereafter, a raw silicon bare wafer was placed on the sample resting electrode so as to indirectly measure the amount of byproducts deposited on the electrode. The idling time was set to be 24 hours and the thickness of the film-like deposition of byproducts adhering to the raw silicon bare wafer during the idling time was measured by an optical instrument for measuring film thickness. The temperature of the coolant for cooling the sample resting electrode during the idling time was set at the same value as that of the sample resting electrode given in the table shown in FIG. 4. During etching process, no voltage is applied to the heater resistor and the temperature control is performed only by the coolant flowing through the sample resting electrode.

According to this embodiment, the preset temperature at which the sample resting electrode is kept during the idling time was 40° C. When this embodiment was not applied, the film thickness of the byproducts deposited on the silicon bare wafer during the idling time was 30 nm. On the other hand, when this embodiment was applied, the film thickness of the byproducts deposited on the silicon bare wafer during the idling time was 0 (zero) nm. Therefore, it can be concluded that the adhesion of byproducts onto the surface of the sample resting electrode 105 is suppressed if the temperature of the sample resting electrode 105 is set higher than 40° C. Further, the same result was obtained when this embodiment was applied to the cleaning process for each lot where there is no wafer existing in the process chamber.

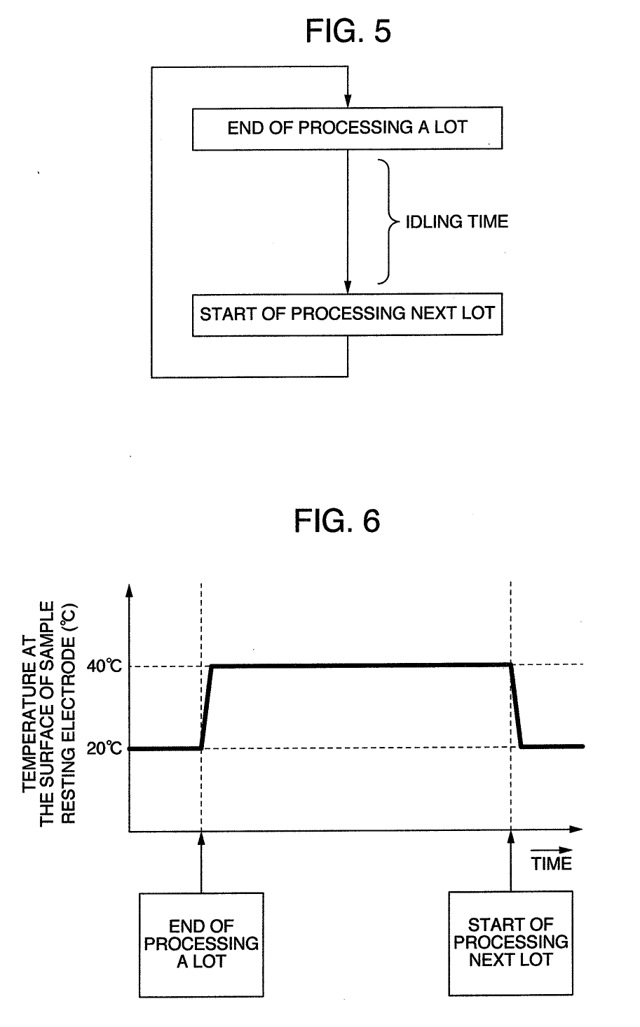

Now, description will be made of a case where this embodiment is applied during the idling time between two successive lots. FIG. 5 shows the steps of a procedure carried out between two successive lots by the plasma processing apparatus shown in FIG. 1. The temperature of the sample resting electrode was controlled by the heater 203 during the idling time between the end of processing a lot and the start of processing the next lot. FIG. 6 graphically shows the change with time in the temperature of the sample resting electrode, illustrating how the temperature of the sample resting electrode is controlled by the heater 203 during the idling time between two successive lots. In this case, the temperature of the sample resting electrode was maintained at 20° C., which is the temperature suitable for etching process, until the end of processing a lot. And as soon as the process of this lot had been finished, the temperature of the sample resting electrode was very quickly elevated to 40° C. by energizing the heater. During the idling time between this lot and the next lot, the temperature of the sample resting electrode was kept at 40° C. by means of the heater. Simultaneously with the start of processing the next lot, the temperature of the sample resting electrode was lowered to 20° C. which is the temperature suitable for etching process. Thus, the adhesion of byproducts onto the surface of the sample resting electrode could be suppressed by maintaining the sample resting electrode at a relatively high temperature during the idling time between two successive lots.

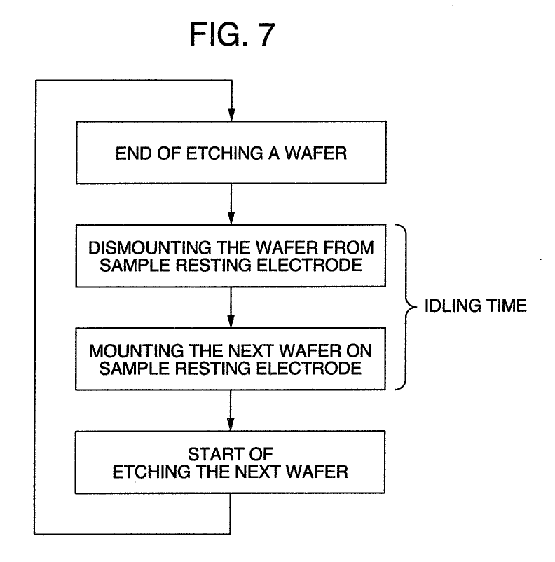

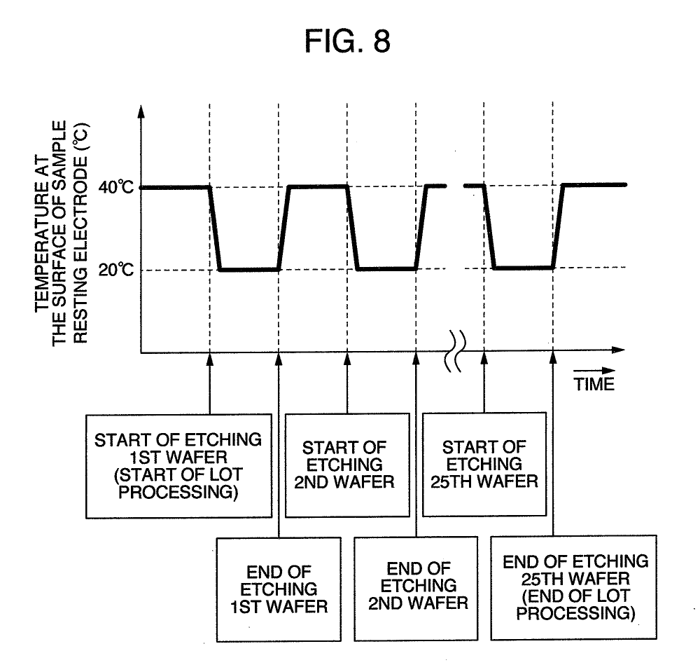

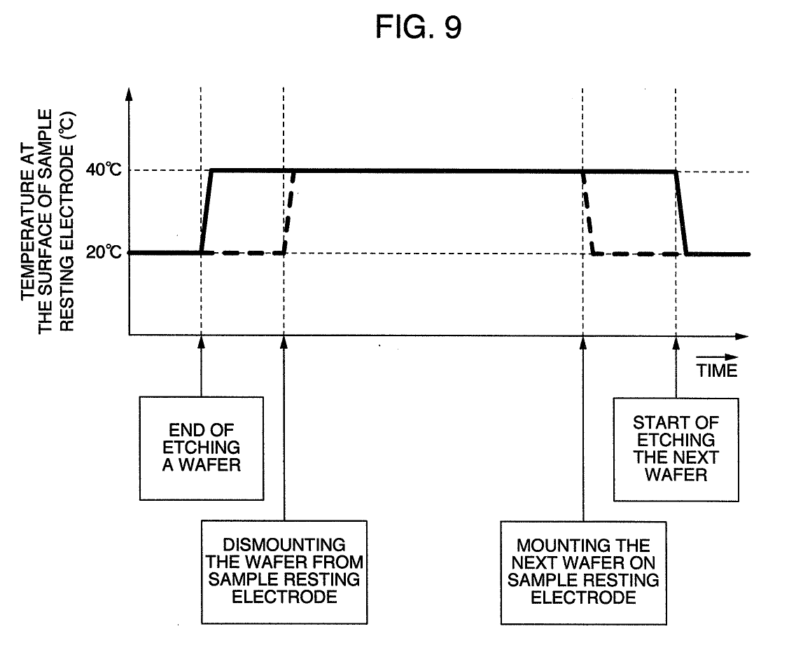

Further, description will be made of a case where this embodiment is applied while a single lot is in process. FIG. 7 shows the steps of a procedure carried out for a lot by the plasma processing apparatus shown in FIG. 1. The temperature of the sample resting electrode was controlled by the heater during the idling time between the end of etching a wafer and the start of etching the next wafer. FIG. 8 graphically shows the change with time in the temperature of the sample resting electrode, illustrating how the temperature of the sample resting electrode is controlled by the heater 203 during the idling time between two successive wafer etching processes. In this case, at the start of etching the wafer, the temperature of the sample resting electrode was kept at 20° C. which is the temperature suitable for etching process. At the end of etching this wafer, the temperature of the sample resting electrode was very quickly elevated to 40° C. by energizing the heater. During the idling time while the same lot was in process, the temperature of the sample resting electrode was kept at 40° C. by energizing the heater. Simultaneously with the start of etching the next wafer, the temperature of the sample resting electrode was lowered to 20° C. which is the temperature suitable for etching process. FIG. 9 graphically shows the change with time in the temperature of the sample resting electrode, illustrating how the temperature of the sample resting electrode is controlled by the heater 203 during the idling time between two successive wafer etching processes in the single lot. As described above, the temperature of the sample resting electrode was very quickly elevated simultaneously with the end of etching a wafer, but the temperature of the sample resting electrode may be very quickly elevated to 40° C. by energizing the heater as soon as the wafer has been dismounted from the sample resting electrode sometime after the end of etching the wafer, as indicated with dotted line in FIG. 9. Further, as described above, the temperature of the sample resting electrode was lowered to 20° C., which is the temperature suitable for etching process, simultaneously with the start of etching the next wafer. But the temperature of the sample resting electrode may be lowered to 20° C., which is the temperature suitable for etching process, as soon as the next wafer has been mounted on the sample resting electrode, as indicated with dotted line in FIG. 9. Thus, the adhesion of byproducts onto the surface of the sample resting electrode could be suppressed by maintaining the sample resting electrode at a relatively high temperature during the idling time between the processes of etching two successive wafers while the same lot was in process.

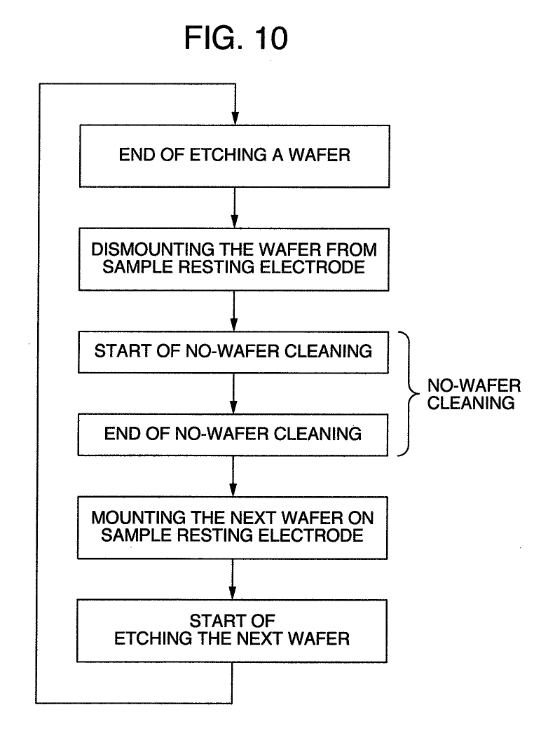

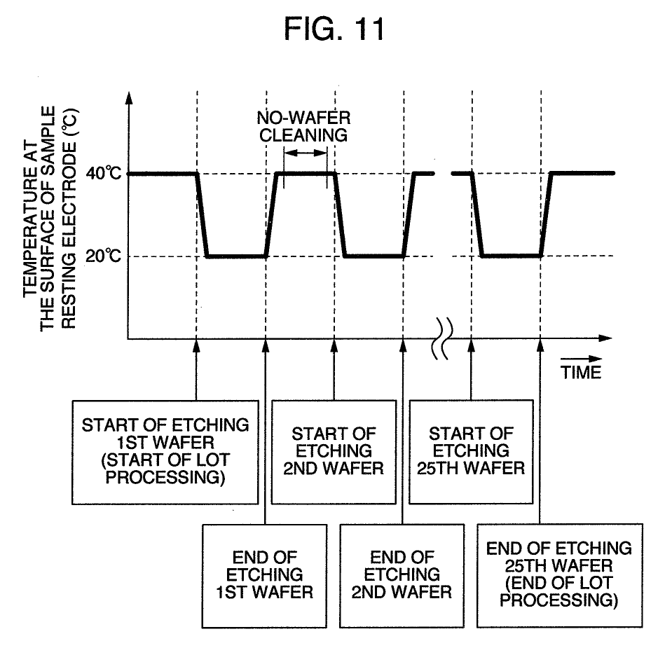

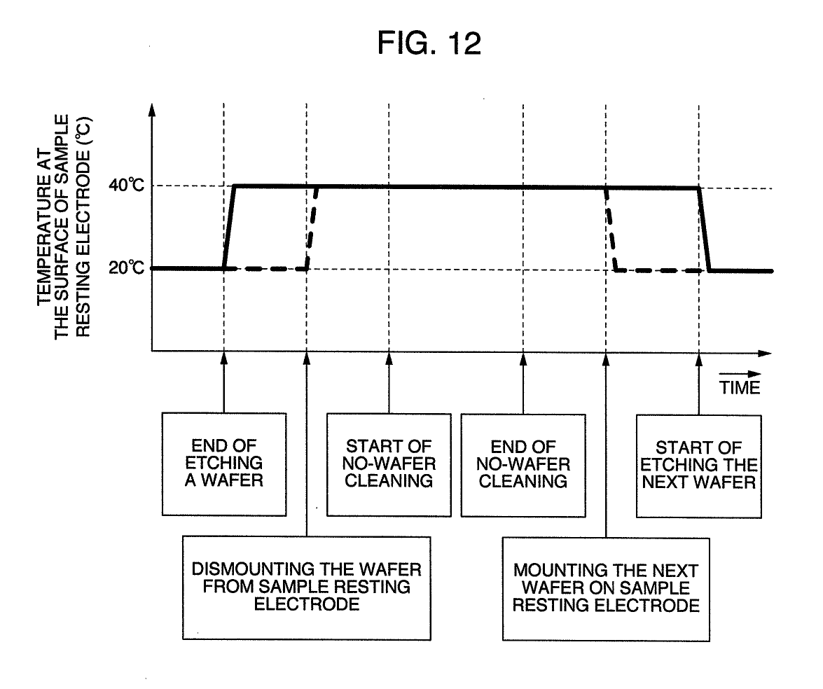

Below is described a case wherein this embodiment was applied to the cleaning process for each lot where there is no wafer existing in the process chamber. FIG. 10 shows the steps of a procedure carried out for the cleaning process for each lot where there is no wafer existing in the process chamber. For the brevity of expression, the “cleaning process for each lot where there is no wafer existing in the process chamber” will be hereafter referred to as the “no-wafer cleaning”. The temperature of the sample resting electrode was controlled by the heater during the no-wafer cleaning time between the end of etching a wafer and the start of etching the next wafer. FIG. 11 graphically shows the change with time in the temperature of the sample resting electrode, illustrating how the temperature of the sample resting electrode is controlled by the heater 203 during the no-wafer cleaning process for each lot. In this case, the temperature of the sample resting electrode was kept at 20° C., which is the temperature suitable for etching process, at the start of etching a wafer and the temperature of the sample resting electrode was very quickly elevated to 40° C. by energizing the heater at the end of etching the wafer. During the no-wafer cleaning time that follows, the temperature of the sample resting electrode was kept at 40° C. by energizing the heater. It was then lowered to 20° C., which is the temperature suitable for etching process, simultaneously with the start of etching the next wafer. FIG. 12 graphically shows the change with time in the temperature of the sample resting electrode in another case, illustrating how the temperature of the sample resting electrode is controlled by the heater 203 during the no-wafer cleaning process for each lot. As described above, the temperature of the sample resting electrode was very quickly elevated simultaneously with the end of etching a wafer. But it may be very quickly elevated to 40° C. by energizing the heater as soon as the wafer has been dismounted from the sample resting electrode after the end of etching the wafer, as indicated with dotted line in FIG. 12. Also, as described above, the temperature of the sample resting electrode was lowered to 20° C., which is the temperature suitable for etching process, simultaneously with the start of etching the next wafer. But it may be lowered to 20° C., which is the temperature suitable for etching process, as soon as the next wafer has been mounted on the sample resting electrode, as indicated with dotted line in FIG. 12. Thus, the adhesion of byproducts onto the surface of the sample resting electrode could be suppressed by maintaining the sample resting electrode at a relatively high temperature during the no-wafer cleaning process for each lot.

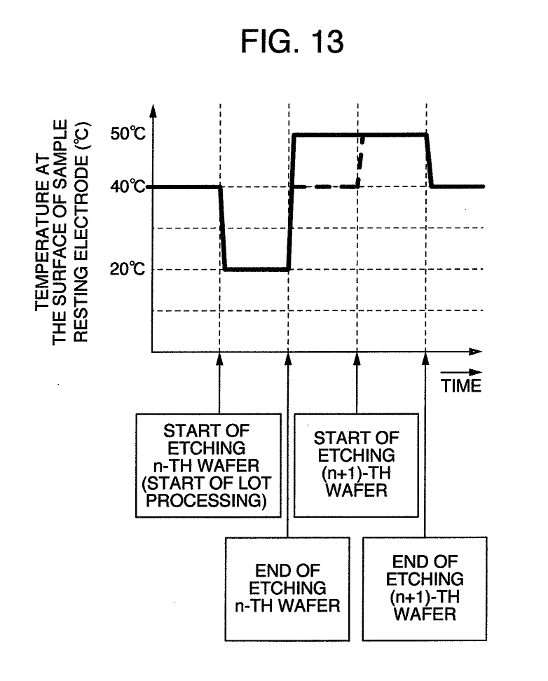

Another embodiment of this invention will be described below wherein the temperature of the sample resting electrode is changed whenever every n wafers have been etched in a lot. FIG. 13 graphically shows the change with time in the temperature of the sample resting electrode, illustrating how the temperature of the sample resting electrode is controlled by the heater 203. When the optimal temperature of the sample resting electrode for etching the n-th wafer was supposed to be 20° C., the temperature of the sample resting electrode was kept at 40° C. during the idling time immediately before etching the n-th wafer. When the optimal temperature of the sample resting electrode for etching the (n+1)-th wafer was supposed to be 50° C., the temperature of the sample resting electrode was kept at 50° C. during the idling time immediately before etching the (n+1)-th wafer. Moreover, as indicated with dotted line in FIG. 13, while the temperature of the sample resting electrode was kept at 40° C. during the idling time immediately before etching the (n+1)-th wafer, the temperature of the sample resting electrode may be elevated to 50° C., which is the temperature suitable for etching the (n+1)-th wafer, by energizing the heater simultaneously with the start of etching the (n+1)-th wafer. Thus, the adhesion of byproducts onto the surface of the sample resting electrode could be suppressed even when the temperature of the sample resting electrode is changed whenever every n wafers have been etched in a lot.

In the application of the temperature control according to this invention to the working process for a laminated layer structure, etched patterns having vertical side walls and only slight errors in photographic patterning could be obtained even after a relatively long idling time. The same results could be obtained when this temperature control method was applied to the case where the idling time is relatively short between the dismounting of a wafer from and the mounting of the next wafer on, the sample resting electrode in the continuous etching process and the case where the no-wafer cleaning is performed for a lot.

According to this invention, etching could be achieved with throughput and precision higher than those attained with the conventional similar techniques.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
a vacuum vessel;
a process chamber housed in the vacuum vessel;
a sample stage located in the process chamber, for supporting on its upper surface a disk-like sample to be processed; and
a means for adjusting a temperature of the sample stage to a predetermined value higher than a temperature at which the samples are processed, during an idling time between successive processes, wherein plural disk-like samples are continuously processed with plasma generated in the process chamber.

2. A plasma processing apparatus as claimed in claim 1, further comprising a heater provided in the sample stage, wherein the temperature of the sample stage is adjusted to the predetermined value by means of the heater.

3. A plasma processing apparatus as claimed in claim 1, wherein the predetermined value is previously selected independent of the conditions for processing the plural disk-like samples.

4. A plasma processing apparatus as claimed in claim 1, wherein the heater is a film-like heater embedded in the dielectric layer which is disposed on the sample stage and on the upper surface of which the sample is mounted.

5. A plasma processing method wherein plural disk-like samples, each of which is placed for processing on an upper surface of the sample stage located in the process chamber housed in the vacuum vessel, are continuously processed with plasma generated in the process chamber, comprising the step of:
adjusting a temperature of the sample stage to a predetermined value higher than a temperature at which the samples are processed, during an idling time between the successive processes.

6. A plasma processing method as claimed in claim 5, wherein the temperature of the sample stage is adjusted to the predetermined value by means of a heater provided in the sample stage.

7. A plasma processing method as claimed in claim 5, wherein the predetermined value is previously selected independent of the conditions for processing the plural disk-like samples.

8. A plasma processing method as claimed in claim 5, wherein the heater is a film-like heater embedded in the dielectric layer which is disposed on the sample stage and on the upper surface of which the sample is mounted.
